(19) United States
(12) Patent Application Publication
(10) Pub. No.: US 2026/0013088 A1
(43) Pub. Date: Jan. 8, 2026

(54) LIQUID-COOLING HEAT DISSIPATION STRUCTURE HAVING NONLINEAR FIN ARRAY

(71) Applicant: AMULAIRE THERMAL TECHNOLOGY, INC., New Taipei City (TW)

(72) Inventors: KUO-WEI LEE, New Taipei City (TW); CHIEN-CHENG WU, New Taipei City (TW); CHUN-LUNG WU, New Taipei City (TW); TZE-YANG YEH, New Taipei City (TW)

(21) Appl. No.: 19/329,521

(22) Filed: Sep. 15, 2025

Related U.S. Application Data
(63) Continuation-in-part of application No. 18/100,474, filed on Jan. 23, 2023.

(51) Int. Cl. H05K 7/20

(52) U.S. Cl. CPC H05K 7/20872

(57) ABSTRACT

A liquid-cooling heat dissipation structure having a nonlinear fin array. The liquid-cooling heat dissipation structure includes an upper plate, a lower plate, and a flow guide member. The upper plate has an accommodating groove of which an inner side has an upper joint area formed thereon. The lower plate has a lower joint area. The flow guide member disposed between the upper plate and the lower plate includes a heat dissipation plate body having a first surface and a second surface, and a plurality of heat dissipation columns integrally disposed on the second surface. The upper brazing area is connected to the lower brazing area, and two ends of the flow guide member are respectively connected to the upper joint area and the lower joint area to form an enclosed cavity for accommodating the heat dissipation columns.

### CROSS-REFERENCE TO RELATED PATENT APPLICATION

This application is a Continuation-In-Part of the U.S. application Ser. NO. 18/100474, filed on January 23, 2023, and entitled "Liquid-Cooling Heat Dissipation Structure Having Nonlinear Fin Array And Method For Manufacturing The Same," now pending, which application is incorporated herein by reference in their entireties.

Some references, which may include patents, patent applications and various publications, may be cited and discussed in the description of this disclosure. The citation and/or discussion of such references is provided merely to clarify the description of the present disclosure and is not an admission that any such reference is "prior art" to the disclosure described herein. All references cited and discussed in this specification are incorporated herein by reference in their entireties and to the same extent as if each reference was individually incorporated by reference.

### FIELD OF THE DISCLOSURE

The present disclosure relates to a liquid-cooling heat dissipation structure having a nonlinear fin array, and more particularly to a liquid-cooling heat dissipation structure having a nonlinear fin array for improving heat dissipation through liquid, which is particularly suitable for heat dissipation of automotive electronics.

### BACKGROUND OF THE DISCLOSURE

Radiators are widely used in various products. Generally, higher-end products adopt water-cooling or liquid-cooling radiators, which have advantages of quietness and a stable cooling performance compared to air- cooling coolers. However, as chips are operating on faster and faster clock speeds, a heat dissipation effect provided by existing liquid coolers are no longer able to meet heat dissipation requirements of such chips.

Specifically, as there are high requirements for heat dissipation and stable performance in automobiles, the water-cooling radiators need to provide maximum heat dissipation efficiency, a stable leak-proof structure, and high reliability.

Therefore, how to improve heat dissipation of the liquid-cooling radiator to overcome the above issues has become one of the important issues to be addressed in the related field.

### SUMMARY OF THE DISCLOSURE

In response to the above-referenced technical inadequacies, the present disclosure provides a liquid-cooling heat dissipation structure having a nonlinear fin array, by which maximum heat dissipation efficiency, a stable leak-proof structure, and high reliability can be achieved.

In one aspect, the present disclosure provides a liquid-cooling heat dissipation structure having a nonlinear fin array, which includes an upper plate, a lower plate, and a flow guide member. The upper plate has an accommodating groove formed by stamping and an upper brazing area arranged around the accommodating groove. An inner side of the accommodating groove has an upper joint area formed thereon. The lower plate has a lower joint area and a lower brazing area arranged around the lower joint area. A position of the lower joint area corresponds to a position of the upper joint area. The flow guide member is disposed between the upper plate and the lower plate. The flow guide member includes a heat dissipation plate body and a plurality of heat dissipation columns that are column shaped. The heat dissipation plate body has a first surface and a second surface opposite to the first surface, and the plurality of heat dissipation columns are integrally disposed on the second surface of the heat dissipation plate body. The first surface of the flow guide member is flush with a bottom surface of the lower plate, and the first surface of the heat dissipation plate body is exposed from the lower plate for being in contact with a plurality of traction inverter power component sets. The upper brazing area of the upper plate is connected to the lower brazing area of the lower plate, and two ends of the flow guide member are respectively connected to the upper joint area and the lower joint area so as to form a cavity that is enclosed for accommodating the plurality of heat dissipation columns. The plurality of heat dissipation columns of the flow guide member are divided from upstream to downstream along a flow path into a plurality of heat dissipation regions corresponding to a plurality of traction inverter power component sets, respectively. A total cross-sectional area of the heat dissipation columns in each of the heat dissipation region becomes larger and larger along the direction of the flow path.

Therefore, in the liquid-cooling heat dissipation structure having the nonlinear fin array provided by the present disclosure, by virtue of "the upper plate has the accommodating groove formed by stamping," "the upper brazing area of the upper plate is connected to the lower brazing area of the lower plate," and "the two ends of the flow guide member are respectively connected to the upper joint area and the lower joint area," a leak-proof ability of the liquid-cooling heat dissipation structure can be strengthened and a reliability of product can be improved.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic cross-sectional view of a liquid-cooling heat dissipation structure according to a first embodiment of the present disclosure;

FIG. 2 is a schematic cross-sectional view of a liquid -cooling heat dissipation structure according to a second embodiment of the present disclosure;

FIG. 3 is a schematic cross-sectional view of a liquid-cooling heat dissipation structure according to a third embodiment of the present disclosure;

FIG. 4 is a schematic cross-sectional view of a liquid-cooling heat dissipation structure according to a fourth embodiment of the present disclosure;

FIG. 5 is a cross-sectional view taken along line V-V of FIG. 4; and

FIG. 6 is a cross-sectional view taken along line VI-VI of FIG. 1 showing a liquid-cooling heat dissipation structure according to a fifth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of "a", "an", and "the" includes plural reference, and the meaning of "in" includes "in" and "on". Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as "first", "second" or "third" can be used to describe various components, signals or the like, which are for distinguishing one component/signal from another one only, and are not intended to, nor should be construed to impose any substantive limitations on the components, signals or the like.

### First Embodiment

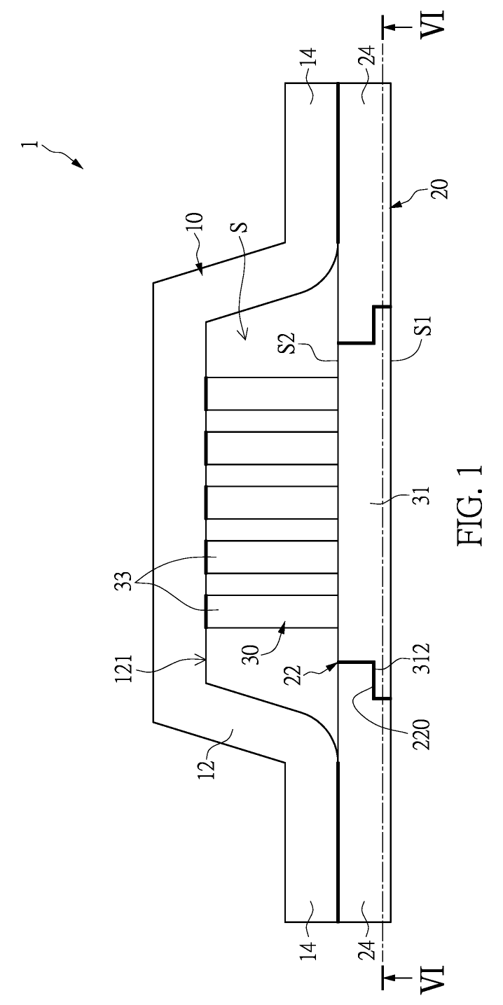

Referring to FIG. 1, one embodiment of the present disclosure provides a liquid-cooling heat dissipation structure 1 having a nonlinear fin array, and more particularly, that is adopted in an enclosed or semi-enclosed automotive liquid-cooling radiator. The liquid-cooling heat dissipation structure having a nonlinear fin array 1 includes an upper plate 10, a lower plate 20, and a flow guide member 30. The flow guide member 30 includes a nonlinear fin array (NFA).

The upper plate 10 has an accommodating groove 12 formed by stamping and an upper brazing area 14. The upper brazing area 14 is arranged around the accommodating groove 12, and the upper brazing area 14 of the present embodiment is generally rectangular frame-shaped. An upper joint area 121 is formed on an inner side of the accommodating groove 12, and the upper joint area 121 is used to be joined to an upper end or a lower end of the flow guide member 30. The accommodating groove 12 is generally rectangular. A material of the upper plate 10 can be copper, copper alloy, aluminum, or aluminum alloy, and can be formed by stamping, molding, etc. However, the present disclosure is not limited thereto.

The lower plate 20 of the present embodiment is in the shape of a flat plate. The lower plate 20 has a lower joint area 22 and a lower brazing area 24. The lower brazing area 24 is arranged around the lower joint area 22, and the lower brazing area 24 of the present embodiment is generally in the shape of a rectangular frame. The upper brazing area 14 corresponds to the lower brazing area 24. A position of the lower joint area 22 substantially corresponds to a position of the upper joint area 121 for being joined to the upper end or the lower end of the flow guide member 30. A material of the lower plate 20 can be copper, copper alloy, aluminum, or aluminum alloy, and can be formed by stamping, molding, etc. However, the present disclosure is not limited thereto.

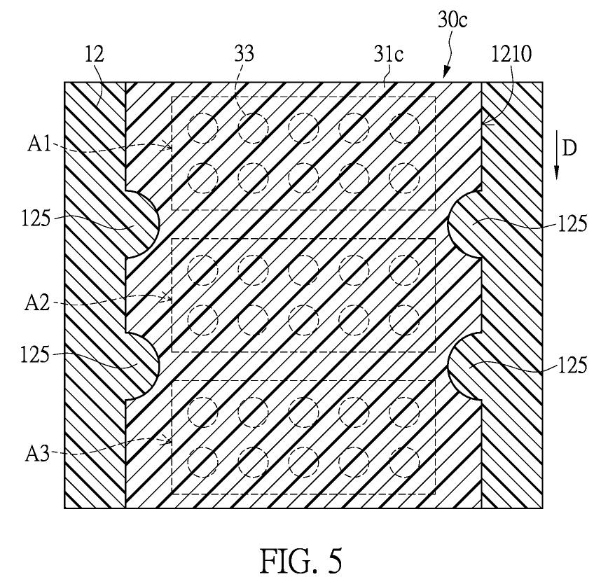

The flow guide member 30 is disposed between the upper plate 10 and the lower plate 20. The flow guide member 30 includes a heat dissipation body 31 and a plurality of heat dissipation columns 33 that are column-shaped. The heat dissipation column 33 can be cylindrical, square column, elliptical column, etc. The heat dissipation plate body 31 has a first surface S1 and a second surface S2 opposite to the first surface S1. The first surface S1 is planar, and the second surface S2 can be planar or non-planar. The plurality of heat dissipation columns 33 of the present embodiment can be integrally disposed on the second surface S2 of the heat dissipation plate body 31. The plurality of heat dissipation columns 33 can be divided into a plurality of fin sets so as to respectively provide heat dissipation to a plurality of heat producing elements. For example, as shown in FIG. 5, three fin sets (or fin regions) of the present embodiment can be divided to respectively be in contact with three traction inverter power component sets, which together form an inverter power module for generating a three-phase alternating current for driving an automotive motor.

In the present embodiment, the upper brazing area 14 of the upper plate 10 is joined to the lower brazing area 24 of the lower plate 20 by brazing. The brazing process adopted by the present disclosure is different from the conventional open radiator using a sealing ring to achieve pressing or locking, so that reliability of the liquid-cooling heat dissipation structure 1 of the present disclosure can be improved. Two ends of the flow guide member 30 are respectively brazed to the upper joint area 121 and the lower joint area 22, After jointing, a cavity S that is enclosed for accommodating the plurality of heat dissipation columns 33 is formed between the accommodating groove 12 of the upper plate 10 and the lower joint area 22 of the lower plate 20. In the present embodiment, the upper end of the flow guide member 30 is brazed to the upper joint area 121, and the lower end of the flow guide member 30 is brazed to the lower joint area 22. After brazing, the upper plate 10, the lower plate 20, and the flow guide member 30 jointly define the cavity S that is enclosed, and the heat dissipation columns are disposed in the cavity S. However, the present disclosure is not limited thereto, and examples will be described in the following.

More specifically, the plurality of heat dissipation columns 33 of the flow guide member 33 are brazed to the upper joint area 121 of the accommodating groove 12, and in one particular embodiment, more than 80% of a total area of a top surface of the plurality of heat dissipation columns 33 is in direct contact (i.e., connection) with the upper joint area 121, thereby strengthening a joint strength between the flow guide member 30 and the upper plate 10. The above mentioned joining process can also be a friction stir welding (FSW) process, which respectively use heat produced by the melting and re-solidification of a solder, and heat produced by friction of a stirring head to soften and mix the material; and then the material is applied to a joint position to implement the joining process. However, the present disclosure is not limited thereto, and other joining methods may also be used to a similar effect. The preferred joint method of the present disclosure includes using the brazing process and the FSW process.

As shown in FIG. 1, in the present embodiment, the lower end of the flow guide member 30 is brazed to the lower joint area 22. In addition, the first surface S1 of the flow guide member 30 is exposed from the lower plate 20. Specifically, a through hole 220 is formed in the lower joint area 22 of the lower plate 20, and a periphery of the heat dissipation plate body 31 of the flow guide member 30 is brazed to a side surface of the through hole 220, so that the first surface S1 of the heat dissipation plate body 31 can be exposed from the lower plate 20. The first surface S1 of the flow guide member 30 can be flush with a bottom surface of the lower plate 20. With such a configuration, the heat dissipation plate body 31 can be in direct contact with the heat producing element (e.g., the traction inverter power component set which is not shown in the figures) so as to provide improved thermal conductivity.

It should be noted that, in the present embodiment, a stepped portion 312 is formed at the periphery of the heat dissipation plate body 31, and the side surface of the through hole 220 are correspondingly formed in a stepped shape. A joint area between the periphery of the heat dissipation plate body 31 and the side surface of the through hole 220 through the stepped structures, so that a joint strength between the heat dissipation plate body 31 and the through hole 220 can be increased and a path across which moisture has to travel can be extended. Therefore, a leak-proof ability of the liquid-cooling heat dissipation structure 1 can be strengthened, and the reliability of the liquid-cooling heat dissipation structure 1 can be improved.

### Second Embodiment

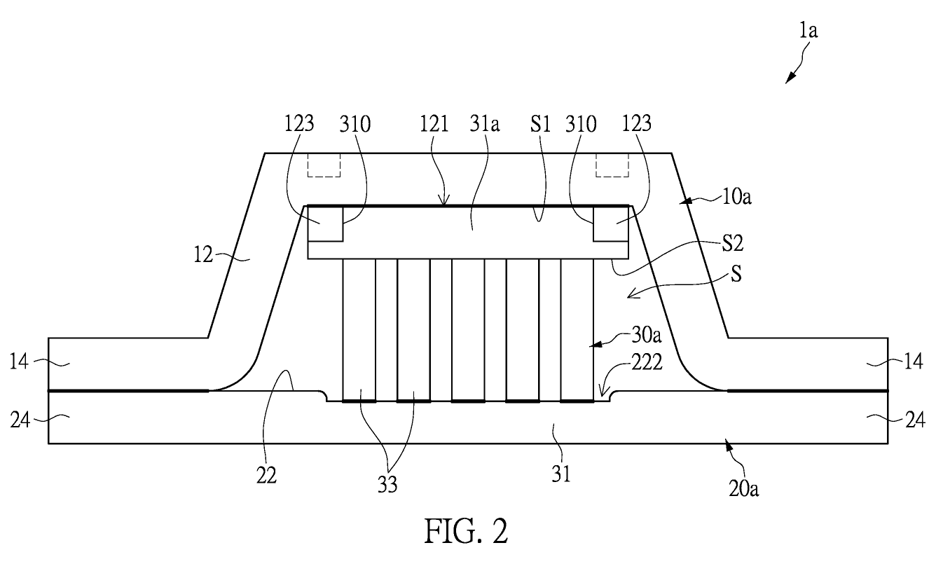

Referring to FIG. 2, the present embodiment provides a liquid-cooling heat dissipation structure la having a nonlinear fin array, which includes an upper plate 10a, a lower plate 20a, and a flow guide member 30a. The difference between the present embodiment and the first embodiment is that, one non-penetrating positioning structure is formed in the upper joint area 121 of the accommodating groove 12, and a heat dissipation plate body 31a of the flow guide member 30a is fixed to the accommodating groove 12 by the non- penetrating positioning structure. The non-penetrating positioning structure indicates that the accommodating groove 12 is not penetrated. The non- penetrating positioning structure can be implemented in certain ways, such as a groove, a bump, and a recessed structure.

In the present embodiment, the non-penetrating positioning structure includes at least two protrusions 123, and the at least two protrusions 123 are snap-fitted to the heat dissipation plate body 31a. The at least two protrusions 123 can match with the heat dissipation plate body 31a in terms of area of shape. Specifically, a height of each of the at least two protrusions 123 is greater than or equal to 0.3 mm and less than or equal to 1 mm. Correspondingly, a recessed portion 310 that faces upward is formed in the heat dissipation plate body 31a. The first surface S1 of the heat dissipation plate body 31a is brazed to the upper joint area 121, and the joining process can also be the FSW process.

Similarly, another non-penetrating positioning structure (also referred to as a non-penetrating lower positioning structure) can be formed in the lower plate 20a so as to be engaged to the guide flow member 30a. The non-penetrating lower positioning structure can be, for example, a plane, a convex, or the recessed structure. In other words, the non-penetrating lower positioning structure is different from the through hole in a penetrating manner of the first embodiment. The lower joint area 22 of the lower plate 20a has a lower groove 222, which is in a shape of a shallow basin and has a flat bottom surface. The plurality of heat dissipation columns 33 of the flow guide member 30a are brazed to the flat bottom surface of the lower groove 22 of the lower joint area 22, and more than 80% of the total area of the top surface of the plurality of heat dissipation columns 33 is in contact with the lower joint area 22, thereby strengthening a joint strength between the flow guide member 30 and the lower plate 20a. The joining process can also be the FSW process.

### Third Embodiment

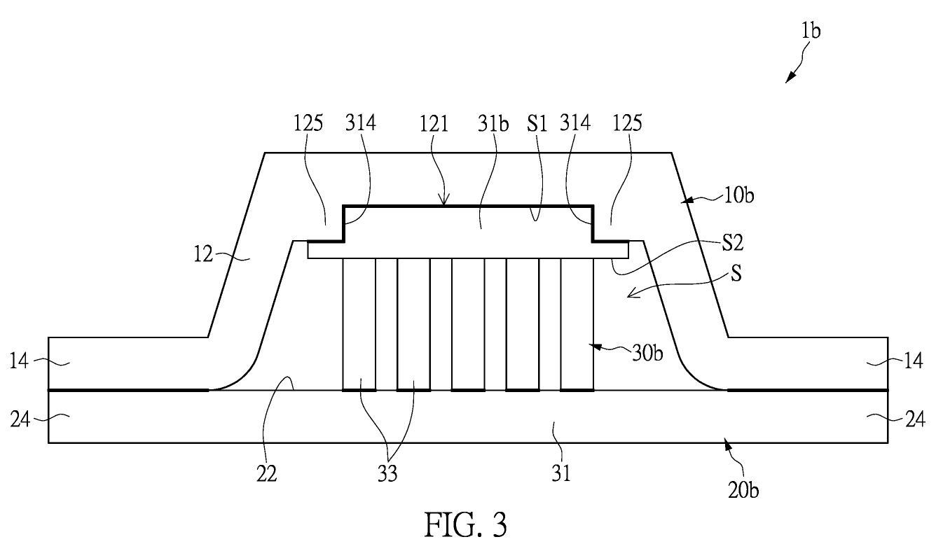

As shown in FIG. 3, the present embodiment provides a liquid-cooling heat dissipation structure lb having a nonlinear fin array, which includes an upper plate lOb, a lower plate 20b, and a flow guide member 30b. The difference between the present embodiment and the first embodiment is that, a non-penetrating positioning structure of the upper joint area 121 includes at least two lateral protrusions 125 each protruding to being recessed toward a side surface of a heat dissipation plate body 31b. Correspondingly, lateral recessed portions 314 are formed on the side surfaces of the heat dissipation plate body 31b. An included angle between a radius of curvature of each of the two lateral protrusions 125 and a longitudinal direction of the heat dissipation column 30b is 75 degrees to 105 degrees. In other words, a protrusion direction of the lateral protrusion 125 can be perpendicular to the side surface of the heat dissipation plate body 31b or slightly inclined by 15 degrees to 25 degrees. However, the present disclosure is not limited thereto, and the non-penetrating positioning structure can also include lateral recessed structures. The first surface S1 of the heat dissipation plate body 31b is brazed to the upper joint area 121, and the joining process can be the brazing process or the FSW process.

In the present embodiment, a non-penetrating lower positioning structure is that, the lower joint area 22 of the lower plate 20b is a planar structure without protrusions or depressions. The lower joint area 22 and the lower brazing area 24 have flat surfaces of equal height and connected to each other. The plurality of heat dissipation columns 33 of the flow guide member 30b are brazed to a top surface of the lower joint area 22. Similarly, more than 80% of the total area of the top surface of the plurality of heat dissipation columns 33 is in contact with the lower joint area 22. The joining process can also be the FSW process.

### Fourth Embodiment

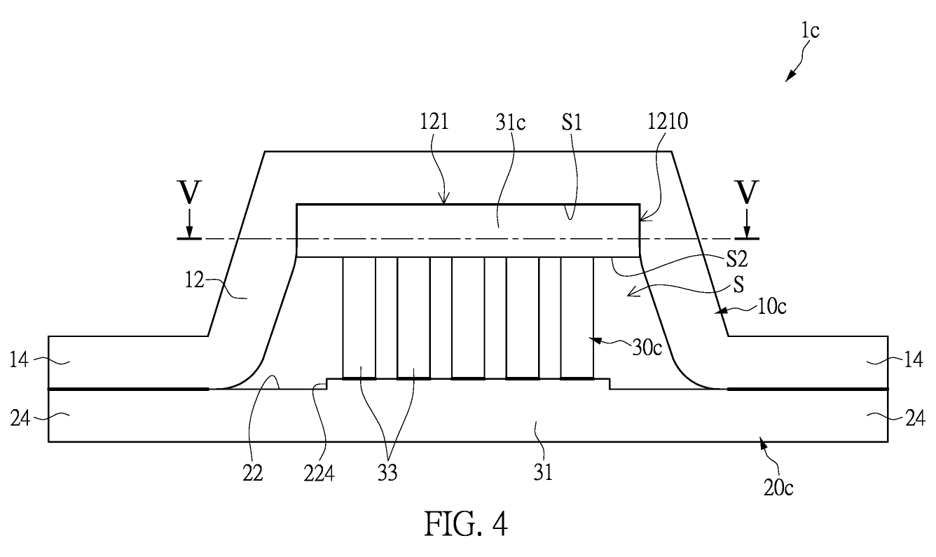

As shown in FIG. 4, the present embodiment provides a liquid-cooling heat dissipation structure lc having a nonlinear fin array, which includes an upper plate lOc, a lower plate 20c, and a flow guide member 30c. The difference between the present embodiment and the third embodiment is that, the non-penetrating positioning structure includes at least one shallow basin- shaped recessed structure 1210, and an area of the shallow basin-shaped recessed structure 1210 is greater than or equal to an area of the first surface S1 of a heat dissipation plate body 31c. Specifically, in one particular embodiment, a depth of a shallowest part of the shallow basin-shaped recessed structure 1210 is greater than or equal to 0.3 mm. The heat dissipation plate body 31 of the flow guide member 30c is disposed in the shallow basin-shaped recessed structure 1210. The first surface S1 of the heat dissipation plate body 31c is brazed to a bottom surface of the shallow basin-shaped recessed structure 1210. The joining process can also be the FSW process.

In the present embodiment, the non-penetrating lower positioning structure is that, the lower joint area 22 of the lower plate 20c has a protrusion 224 that is platform-shaped. One end of the flow guide member 30c (i.e., the plurality of heat dissipation columns 33) is brazed to the protrusion 224. Similarly, more than 80% of the total area of the top surface of the plurality of heat dissipation columns 33 is in contact with the lower joint area 22. The joining process can also be the FSW process.

Referring to FIG. 5 , FIG. 5 is a schematic cross-sectional view according to FIG. 4 . In addition to including the shallow basin-shaped recessed structure 1210, the upper joint area 121 can also include the lateral protrusion 125. The plurality of heat dissipation columns 33 of the flow guide member 30c can be divided from upstream to downstream along a flow path D (referring to the arrow shown in FIG. 5 ) into a first heat dissipation area A1, a second heat dissipation area A2, and a third heat dissipation area A3, corresponding to three traction inverter power component sets (not shown in the figures).

In the present embodiment, a cross section of each of the heat dissipation columns 33 in the first heat dissipation area A1, the second heat dissipation area A2, and the third heat dissipation area A3 is circle shaped. However, the present disclosure is not limited thereto. For example, the cross section of each of the heat dissipation columns 33 in the first heat dissipation area A1 can be drop-shaped or oval-shaped, and the cross section of each of the heat dissipation columns 33 in the second heat dissipation area A2 and the third heat dissipation area A3 can be rectangular or circular.

Further, in the present embodiment, the heat dissipation columns 33 in the first heat dissipation area A1, the second heat dissipation area A2, or the third heat dissipation area A3 are spaced apart from each other. However, the present disclosure is not limited thereto. For example, an average distance between the heat dissipation columns 33 in the first heat dissipation area A1 is greater than an average distance between the heat dissipation columns 33 in the second heat dissipation area A2, and the average distance between the heat dissipation columns 33 in the second heat dissipation area A2 is greater than or equal to an average distance between the heat dissipation columns 33 in the third heat dissipation area A3.

In order to implement the above liquid-cooling heat dissipation structure, the present disclosure further provides a method of manufacturing the liquid-cooling heat dissipation structure having the nonlinear fin array. Taking the first embodiment as an example, but it can be applied the other embodiments, the method includes the following steps.

Step (a) is to provide an upper plate 10 and stamp the upper plate 10 to form an accommodating groove 12. An upper joint area 121 is formed on an inner side of the accommodating groove 12, and an upper brazing area 14 is formed around the accommodating groove 12.

Step (b) is to provide a lower plate 20 and stamp the lower plate 20 to form a lower joint area 22. A position of the lower joint area 22 corresponds to a position of the upper joint area 121, and a lower brazing area 24 is formed around the lower joint area 22.

Step (c) is to provide a flow guide member 30 and form a heat dissipation plate body 31 and a plurality of heat dissipation columns 33 that are column shaped. The heat dissipation plate body 31 has a first surface S1 and a second surface S2 opposite to the first surface S1. The plurality of heat dissipation columns 33 are integrally disposed on the second surface S2 of the heat dissipation plate body 31.

Step (d) is to braze the upper brazing area 14 of the upper plate 10 to the lower brazing area 24 of the lower plate 20. A cavity S that is enclosed for accommodating the flow guide member 30 is formed between the accommodating groove 12 and the lower joint area 22.

Step (e) is to braze two ends of the flow guide member 30 to the upper joint area 121 and the lower joint area 22, respectively.

The flow guide member 30 can be formed by forging, a groove forming process, injection molding, or laminate molding. When the flow guide member 30 is formed by forging or the groove forming process, the flow guide member 30 is made of copper, copper alloy, aluminum, or aluminum alloy. When the flow guide member 30 is formed by injection molding, the flow guide member 30 is made of copper or copper alloy. When the flow guide member 30 is formed by laminate molding, the flow guide member 30 is made of aluminum or aluminum alloy. The adoption of the above processes can achieve a cost reduction of the flow guide member 30. Such manufacturing method can provide the flow guide member integrally formed, so that an assembly tolerance can be avoided and production efficiency can be increased. Further, the flow guide member 30 integrally formed has an improved structural strength and can maximize a heat dissipation effect.

### Fifth Embodiment

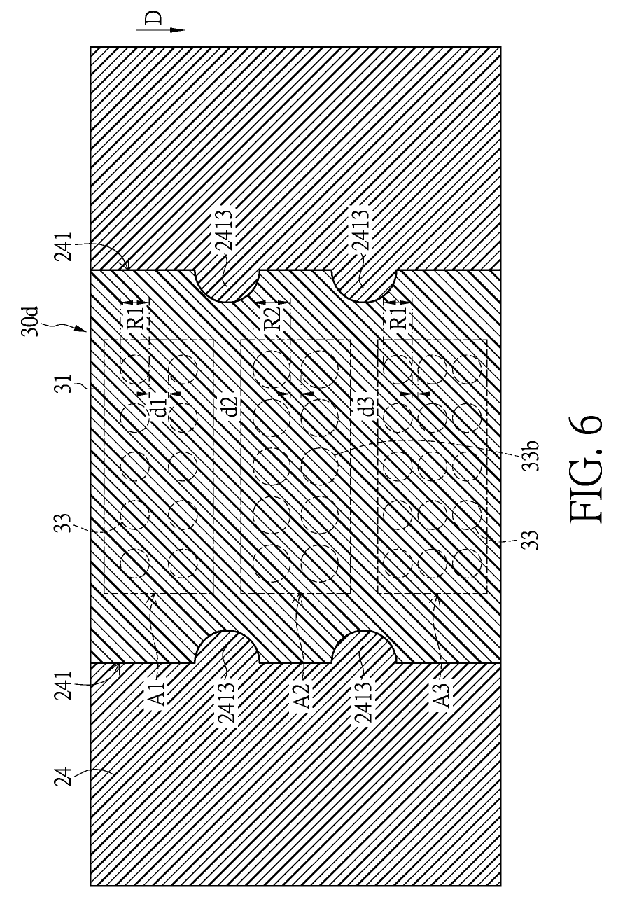

Referring to FIG. 6, the liquid-cooling heat dissipation structure of this embodiment provides a nonlinear fin array, which includes an upper plate 10, a lower plate 20, and a flow guide member 30d, as shown in FIG. 1. The flow guide member 30c includes a nonlinear fin array (NFA). The flow guide member 30d is disposed between the upper plate 10 and the lower plate 20. The flow guide member 30d includes a heat dissipation body 31 and a plurality of heat dissipation columns 33, 33b, 33 that are column-shaped.

In this embodiment, the flow guide member 30d is divided from upstream to downstream along a flow path D (referring to the arrow shown in FIG. 6) into three heat dissipation regions, which are a first heat dissipation region A1, a second heat dissipation region A2, and a third heat dissipation region A3, corresponding to three traction inverter power component sets (not shown in the figures). Three heat dissipation regions Al to A3 have the same area.

Different from the fourth embodiment, this embodiment arranges the three groups of heat dissipation columns having different configurations along the direction of the flow path D from upstream to downstream. In general, the total cross-sectional areas of the heat dissipation columns in each of the heat dissipation region becomes larger and larger along the direction of the flow path D.

An exemplified arrangement according to this embodiment is described as follows. The first heat dissipation region Al includes ten heat dissipation columns 33. Each heat dissipation column 33 has a first diameter R1, and a first interval distance R1 is arranged between adjacent two of the heat dissipation columns 33. The number of the heat dissipation columns 33 in the first heat dissipation region A1 is the same as the number of the heat dissipation columns 33b in the second heat dissipation region A2. The second heat dissipation region A2 includes ten heat dissipation columns 33b. Each heat dissipation column 33b has a second diameter R2, and a second interval distance R2 is arranged between adjacent two of the heat dissipation columns 33b. The second interval distance R2 is smaller than the first interval distance R1. In other words, the total cross-sectional areas of the heat dissipation columns 33b in the second heat dissipation region A2 is larger than the total cross-sectional areas of the heat dissipation columns 33 in the first heat dissipation region A1.

The number of the heat dissipation columns 33 in the third heat dissipation region A3 is larger than the number of the heat dissipation columns 33b in the second heat dissipation region A2. The third heat dissipation region A3 includes fifteen heat dissipation columns 33. Each heat dissipation column 33 has a first diameter R1, and a third interval distance R3 is arranged between adjacent two of the heat dissipation columns 33. The third interval distance R3 is smaller than the first interval distance R1, and is also smaller than the second interval distance R2. In other words, the total cross-sectional areas of the heat dissipation columns 33 in the third heat dissipation region A3 is larger than the total cross-sectional areas of the heat dissipation columns 33b in the second heat dissipation region A2.

Further, the lower brazing area 24 has a bond intensifying structure 241 that is brazed to the heat dissipation plate body 31 of the flow guide member 30d. The bond intensifying structure 241 has a plurality of lateral protrusions 2413 that is protruded toward the heat dissipation plate body 31.

### Beneficial Effects of the Embodiments

In conclusion, in the liquid-cooling heat dissipation structure 1 having the nonlinear fin array provided by the present disclosure, by virtue of "the upper plate 10 has the accommodating groove 12 formed by stamping," "the upper brazing area 14 of the upper plate 10 is connected to the lower brazing area 24 of the lower plate 20" and "the two ends of the flow guide member 30 are respectively connected to the upper joint area 121 and the lower joint area 22," the leak-proof ability of the liquid-cooling heat dissipation structure 1 can be strengthened and a reliability of product can be improved.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A liquid-cooling heat dissipation structure having a nonlinear fin array,comprising:an upper plate having an accommodating groove formed by stamping and an upper brazing area arranged around the accommodating groove, an inner side of the accommodating groove having an upper joint area formed thereon;a lower plate having a lower joint area and a lower brazing area arranged around the lower joint area, a position of the lower joint area corresponding to a position of the upper joint area; anda flow guide member disposed between the upper plate and the lower plate, wherein the flow guide member includes a heat dissipation plate body and a plurality of heat dissipation columns that are column shaped, the heat dissipation plate body has a first surface and a second surface opposite to the first surface, and the plurality of heat dissipation columns are integrally disposed on the second surface of the heat dissipation plate body;wherein the first surface of the flow guide member is flush with a bottom surface of the lower plate, and the first surface of the heat dissipation plate body is exposed from the lower plate for being in contact with a plurality of traction inverter power component sets;wherein the upper brazing area of the upper plate is connected to the lower brazing area of the lower plate, and two ends of the flow guide member are respectively connected to the upper joint area and the lower joint area so as to form a cavity that is enclosed for accommodating the
plurality of heat dissipation columns;wherein the plurality of heat dissipation columns of the flow guide member are divided from upstream to downstream along a flow path into a plurality of heat dissipation regions corresponding to a plurality of traction inverter power component sets, respectively;wherein a total cross-sectional area of the heat dissipation columns in each of the heat dissipation region becomes larger and larger along the direction of the flow path.

2. The liquid-cooling heat dissipation structure according to claim 1, wherein a through hole is formed in the lower joint area of the lower plate, a periphery of the heat dissipation plate body of the flow guide member is connected to a side surface of the through hole.

3. The liquid-cooling heat dissipation structure according to claim 2, wherein a stepped portion is formed on the periphery of the heat dissipation plate body, and a side surface surrounding the through hole is correspondingly formed in a stepped shape so as to correspond to each other.

4. The liquid-cooling heat dissipation structure according to claim 1, wherein the lower joint area of the lower plate is a planar structure.

5. The liquid-cooling heat dissipation structure according to claim 1, wherein the lower joint area of the lower plate has a lower groove, and one end of the flow guide member is connected to a bottom surface of the lower
groove.

6. The liquid-cooling heat dissipation structure according to claim 1, wherein the lower joint area of the lower plate has a protrusion, and one end of the flow guide member is connected to the protrusion.

7. The liquid-cooling heat dissipation structure according to claim 1, wherein more than 80% of a total area of a top surface of the plurality of heat dissipation columns of the flow guide member is joined with the upper joint area or the lower joint area.

8. The liquid-cooling heat dissipation structure according to claim 1, wherein the upper joint area of the accommodating groove has a non-penetrating positioning structure formed therein, and the heat dissipation plate body of the flow guide member is fixed to the accommodating groove through the non-penetrating positioning structure.

9. The liquid-cooling heat dissipation structure according to claim 8, wherein the non-penetrating positioning structure has at least two protrusions, the at least two protrusions are snap-fitted to the heat dissipation plate body, and a height of each of the at least two protrusions is greater than or equal to 0.3 mm and less than or equal to 1 mm.

10. The liquid-cooling heat dissipation structure according to claim 8, wherein the non-penetrating positioning structure has at least two lateral protrusions
or at least two recessed structures each protruding or being recessed toward a side surface of the heat dissipation plate body, and an included angle between a radius of curvature of each of the two lateral protrusions or recessed structures and a longitudinal direction of the heat dissipation column is 75 degrees to 105 degrees.

11. The liquid-cooling heat dissipation structure according to claim 8, wherein the non-penetrating positioning structure has at least one recessed structure, an area of the at least one recessed structure is greater than or equal to an area of the first surface of the heat dissipation plate body, and a depth of a shallowest part of the recessed structure is greater than or equal to 0.3 mm.

12. The liquid-cooling heat dissipation structure according to claim 1, wherein a cross section of each of the heat dissipation columns in the first heat dissipation region is drop-shaped or oval-shaped, and a cross section of each of the heat dissipation columns in the second heat dissipation region and the third heat dissipation region is rectangular or circular.

13. The liquid-cooling heat dissipation structure according to claim 1, wherein the flow guide member is divided from upstream to downstream along the flow path into a first heat dissipation region, a second heat dissipation region, and a third heat dissipation region; wherein a total cross-sectional area of the heat dissipation columns in the second heat dissipation region is larger than a total cross-sectional area of the heat dissipation columns in the first heat dissipation region; wherein a total cross-sectional area of the heat dissipation columns in the third heat dissipation region is larger than a total cross-sectional area of the heat dissipation columns in the second heat dissipation region.

14. The liquid-cooling heat dissipation structure according to claim 13, wherein a number of the heat dissipation columns in the first heat dissipation region is the same as a number of the heat dissipation columns in the second heat dissipation region; wherein each of the heat dissipation columns of the first heat dissipation region has a first diameter, and a first interval distance arranged between adjacent two of the heat dissipation columns of the first heat dissipation region; each of the heat dissipation columns of the second heat dissipation region has a second diameter, and a second interval distance arranged between adjacent two of the heat dissipation columns of the second heat dissipation region; wherein the second interval distance is smaller than the first interval distance.

15. The liquid-cooling heat dissipation structure according to claim 14, wherein a number of the heat dissipation columns in the third heat dissipation region is larger than a number of the heat dissipation columns in the second heat dissipation region; each of the heat dissipation column has a first diameter, and a third interval distance arranged between adjacent two of the heat dissipation columns, the third interval distance is smaller than the first interval distance and is also smaller than the second interval distance.

16. The liquid-cooling heat dissipation structure according to claim 1, wherein the lower brazing area has a bond intensifying structure that is brazed to the heat dissipation plate body of the flow guide member, the bond intensifying 111P001235US.CIP5structure has a plurality of lateral protrusions that is protruded toward the heat dissipation plate body.

17. The liquid-cooling heat dissipation structure according to claim 1, wherein each of the upper plate and the lower plate is made of copper, copper alloy, aluminum, or aluminum alloy; wherein, when the flow guide member is formed by forging or a groove forming process, the flow guide member is made of copper, copper alloy, aluminum, or aluminum alloy; wherein, when the flow guide member is formed by injection molding, the flow guide member is made of copper or copper alloy; wherein, when the flow guide member is formed by laminate molding, the flow guide member is made of aluminum or aluminum alloy.
